(19) United States
(12) Patent Application Publication
(10) Pub. No.: US 2026/0006864 A1
(43) Pub. Date: Jan. 1, 2026

(54) SEMICONDUCTOR DEVICE AND METHOD OF FABRICATING THE SAME

(71) Applicant: WUHAN XINXIN SEMICONDUCTOR MANUFACTURING CO., LTD., Wuhan (CN)

(72) Inventors: Ruizhang XU, Wuhan (CN); Le LI, Wuhan (CN)

(21) Appl. No.: 19/246,111

(22) Filed: Jun. 23, 2025

(30) Foreign Application Priority Data
Jun. 27, 2024 (CN) 202410841658.9

(51) Int. Cl. H10D 62/10; H10D 30/01; H10D 30/60; H10D 64/27; H10D 64/66

(52) U.S. Cl. CPC H10D 62/102; H10D 30/023; H10D 30/611; H10D 64/519; H10D 64/675

(57) ABSTRACT

The present disclosure provides a semiconductor device and a method of fabricating the same. The semiconductor device includes: a substrate; a gate layer formed over the substrate, which includes a main gate and an extended gate spaced apart from each other; and an insulating dielectric layer formed on the substrate and connecting the main gate and the extended gate. The present disclosure allows the gate layer to function as desired while avoiding performance of the semiconductor device from being degraded due to the presence of parasitic capacitance.

### CROSS-REFERENCES TO RELATED APPLICATION

This application claims the priority of Chinese patent application number 202410841658.9, filed on Jun. 27, 2024 and entitled “SEMICONDUCTOR DEVICE AND METHOD OF FABRICATING THE SAME”, the entire contents of which are incorporated herein by reference.

### TECHNICAL FIELD

The present disclosure relates to the fabrication of semiconductor integrated circuits, and particular to a semiconductor device and a method of fabricating the same.

### BACKGROUND

In semiconductor devices, body ties are commonly provided by body-tied-to-source (BTS), T-gate, H-gate and like structures. For example, FIG. 1 shows a device employing a T-gate structure. As can be seen from the figure, a T-gate layer 11 is formed over a substrate. A source region 12 and a drain region 13 are formed in the substrate on opposite sides of a vertical arm of the T-gate layer 11. A body contact region 14 is formed in the substrate on the side of a horizontal arm of the T-gate layer 11 away from the source region 12 and the drain region 13. During the fabrication of a device with the T-gate structure of FIG. 1, a border AA′ of an ion-implanted region A1 for the source region 12 and the drain region 13 and an ion-implanted region A2 for the body contact region 14 must reside on the horizontal arm of the T-gate layer 11. Otherwise, the extents of the resulting source region 12, drain region 13 and body contact region 14 may be undesirable and lead to degraded performance of the device.

Limited by the critical dimensions (CDs) of the processes used to form the gate layer 11, the source region 12, the drain region 13 and the body contact region 14 and variations in alignment accuracy of the photomasks used, a gate length L1 of the horizontal arm of the gate layer 11 measured in the direction from the source region 12 to the body contact region 14 should not be made too small (e.g., not less than 0.3 μm). On the other hand, an excess of this gate length L1 may lead to increased parasitic capacitance, which is detrimental to the performance of the resulting device.

Therefore, how to enable the gate layer to function as desired while avoiding parasitic capacitance induced degradation of the device's performance remains a problem requiring urgent attention.

### SUMMARY

It is an object of the present disclosure to provide a semiconductor device and a method of fabricating the device, which allows a gate layer in the device to function as desired while avoiding parasitic capacitance induced performance degradation of the device.

To this end, the present disclosure provides a semiconductor device including:
a substrate;
a gate layer formed over the substrate, which includes a main and an extended gate spaced apart from each other; and
an insulating dielectric layer formed on the substrate, and the insulating dielectric layer connecting the main gate and the extended gate.

The present disclosure also provides a method of fabricating a semiconductor device, which includes:
providing a substrate;
forming a gate layer over the substrate, which includes a main and an extended gate separated apart from each other; and
forming an insulating dielectric layer on the substrate, which connects the main gate and the extended gate.

The present disclosure has the following benefits over the prior art:

1. It provides a semiconductor device including: a gate layer formed over a substrate, which includes a main and an extended gate spaced apart from each other; and an insulating dielectric layer formed on the substrate and connecting the a main gate and an extended gate. With this arrangement, the gate layer can function as desired, and the semiconductor device can be avoided from any degradation in performance arising from parasitic capacitance.

2. It also provides a method of fabricating a semiconductor device, which includes: forming a gate layer over a substrate, which includes a main gate and an extended gate spaced apart from each other; and forming an insulating dielectric layer on the substrate, which connects the main gate and the extended gate. With this arrangement, the gate layer can function as desired, and the resulting semiconductor device can be avoided from any degradation in performance arising from parasitic capacitance.

### BRIEF DESCRIPTION OF THE DRAWINGS

FIG. 1 is a schematic top view of a conventional device with a T-gate structure.

FIG. 2 is a schematic illustration of a semiconductor device according to a first embodiment of the present disclosure.

FIG. 3 is a schematic illustration of a semiconductor device according to a second embodiment of the present disclosure.

FIG. 4 is a flowchart of a method of fabricating a semiconductor device according to an embodiment of the present disclosure.

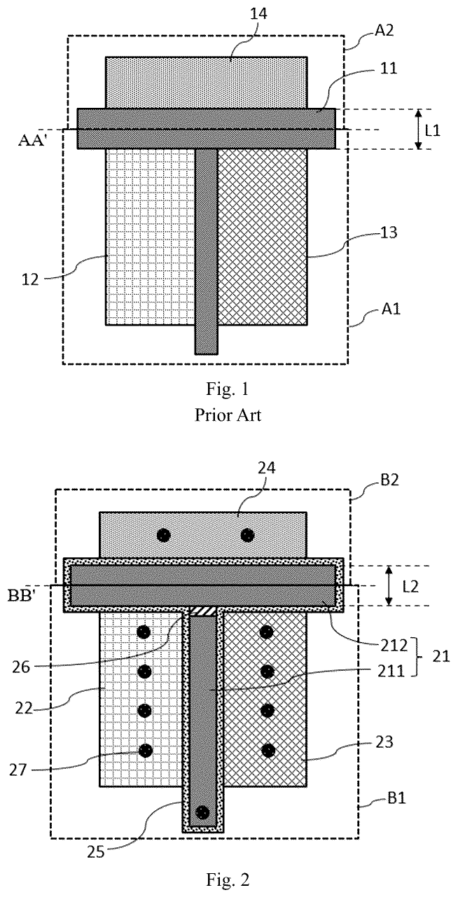

In FIGS. 1 to 4,
11 denotes a gate layer; 12, a source region; 13, a drain region; 14, a body contact region; 21, a gate layer; 211, a main gate; 212, an extended gate; 22, a source region; 23, a drain region; 24, a body contact region; 25, a spacer; 26, an insulating dielectric layer; and 27, a conductive plug.

### DETAILED DESCRIPTION

Objects, features and advantages of the present disclosure will become more apparent upon reading the following detailed description of semiconductor devices and fabrication methods proposed herein. Note that the figures are provided in a very simplified form not necessarily drawn to exact scale for the only purpose of helping to explain the disclosed embodiments in a more convenient and clearer way.

In one embodiment of the present disclosure, there is provided a semiconductor device including: a substrate; a gate layer formed over the substrate, which includes a main and an extended gate spaced apart from each other; and an insulating dielectric layer formed on the substrate and connecting the a main and an extended gate.

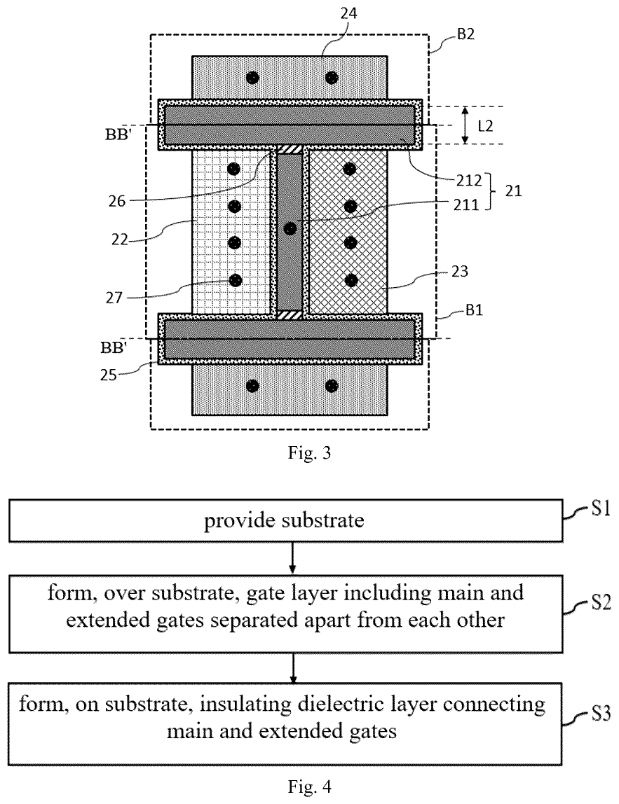

The semiconductor device of this embodiment is described in detail below with reference to FIGS. 2 to 3, which schematically illustrate the device in top views.

The substrate may be either a single-layer structure, or a multi-layer structure consisting of multiple layers of the same or different materials. Without limitation, examples of the material of the substrate may include semiconductor materials, such as Si, SiGe, SiGeC, SiC, GaAs, InAs, InP and other III/V or II/VI compound semiconductors, or the substrate may be a layered substrate, such as Si/SiGe, Si/SiC, silicon on insulator (SOI) or silicon germanium on insulator (SiGeOI).

An active area (not shown) is formed in the substrate, which is surrounded by a trench isolation structure (not shown). A top surface of the trench isolation structure may be flush with, slightly lower than, or slightly higher than a top surface of the substrate. The trench isolation structure may be made of silicon oxide, silicon oxynitride or the like.

The gate layer 21 is formed over the substrate. The gate layer 21 includes a main gate 211 and an extended gate 212, which are spaced apart from each other. That is, there is a gap between the main gate 211 and the extended gate 212, which electrically isolates them from each other.

A gate dielectric layer (not shown) is formed between the gate layer 21 and the substrate. The gate layer 21, the gate dielectric layer and the substrate make up a capacitive structure.

The gate dielectric layer may be made of silicon oxide (with a relative dielectric constant of 4.1) or another dielectric material. Constructing the gate dielectric layer with a low-k material can reduce the capacitance.

The insulating dielectric layer 26 is formed on the substrate. The insulating dielectric layer 26 connects the main gate 211 and the extended gate 212. That is, the insulating dielectric layer 26 fills the gap between, and thereby connects, the main gate 211 and the extended gate 212. These connections are mechanical, but not electrical. That is, the insulating dielectric layer 26 electrically insulates the main gate 211 and the extended gate 212 from each other.

The insulating dielectric layer 26 includes at least one of silicon oxide, silicon nitride, silicon oxynitride and optionally other materials.

As shown in FIG. 2, the main gate 211 and the extended gate 212 may make up a T-shaped structure, together with the insulating dielectric layer 26 that connects them. In this case, the main gate 211 provides a vertical arm of the T-shaped structure, and the extended gate 212 provides a horizontal arm of the T-shaped structure. The insulating dielectric layer 26 may be located at the end of the vertical arm of the T-shaped structure closer to the horizontal arm, or on the side of the horizontal arm of the T-shaped structure adjacent to the vertical arm. Alternatively, as shown in FIG. 3, the main gate 211 and the extended gate 212 may make up an H-shaped structure, together with the insulating dielectric layer 26 that connects them. In this case, the main gate 211 provides a horizontal arm of the H-shaped structure, and the extended gate 212 provides vertical arms of the H-shaped structure. The insulating dielectric layer 26 may be located at the opposite ends of the horizontal arm of the H-shaped structure, or on the sides of the vertical arms of the H-shaped structure adjacent to the horizontal arm.

In one embodiment, the extended gate 212 extends at opposite ends from over the active area to over the trench isolation structure. In case of the T-shaped structure being made of the main gate 211, the extended gate 212 and the insulating dielectric layer 26 that connects the two, according to one embodiment, the main gate 211 may extend, at the end away from the extended gate 212, from over the active area to over the trench isolation structure.

The semiconductor device further includes a source region 22 and a drain region 23, which are formed both in the substrate on opposite sides of the main gate 211 and the insulating dielectric layer 26. A region under the main gate 211 between the source region 22 and the drain region 23 functions as a channel region.

The insulating dielectric layer 26 can prevent a connection from being established between the source region 22 and the drain region 23 during the formation of the two regions by ion implantation, which can lead to a short circuit.

The semiconductor device further includes a body contact region 24, the body contact region 24 is formed in the substrate on the side of the extended gate 212 away from the main gate 211.

The body contact region 24 is formed to connect the substrate under the channel region (i.e., a body region). The trench isolation structure surrounds the source region 22, the drain region 23 and the body contact region 24.

The main gate 211 acts as a gate electrode of the semiconductor device, and the extended gate 212 acts to isolate both the source region 22 and the drain region 23 from the body contact region 24.

The source region 22 and the drain region 23 are of the same doping type, which is opposite to that of the body contact region 24. When the doping types of the body contact region 24 and the source region 22 are opposite, the semiconductor device is an enhancement-mode field effect transistor.

In case of the body contact region 24 and the source region 22 being of opposite doping types, if the source region 22 and the drain region 23 are n-type regions, then the body contact region 24 is a p-type region. On the contrary, if the source region 22 and the drain region 23 are p-type regions, then the body contact region 24 is an n-type region.

The semiconductor device further includes a spacer 25 formed on sidewalls of the main gate 211 and the extended gate 212.

Preferably, the insulating dielectric layer 26 and the spacer 25 are formed of the same material in a single process. That is, at the same time as the spacer 25 is formed on the sidewalls of the main gate 211 and the extended gate 212, the material of the spacer 25 is also filled in the gap between the main gate 211 and the extended gate 212. The material of the spacer 25 filled in the gap acts as the insulating dielectric layer 26. That is, the main gate 211 and the extended gate 212 are connected by part of the spacer 25 (that acts as the insulating dielectric layer 26).

In one embodiment, a layer of insulating material is formed on the substrate and the gate layer 21, which covers a top surface of the substrate and the sidewalls and a top surface of the gate layer 21 and fills the gap between the main gate 211 and the extended gate 212, and portions of the layer of insulating material on the top surfaces of the substrate and the gate layer 21 are then removed by mask-less etching (performed normal to the substrate). The remainder of the layer of insulating material provides both the spacer 25 on the sidewalls of the gate layer 21 and the insulating dielectric layer 26 in the gap between the main gate 211 and the extended gate 212.

In an alternative embodiment, the insulating dielectric layer 26 and the spacer 25 may be formed in separate processes. In this case, the spacer 25 may also cover sidewalls of the insulating dielectric layer 26.

In an alternative embodiment, the insulating dielectric layer 26 may be formed only in the gap between the main gate 211 and the extended gate 212.

The insulating dielectric layer 26 should completely fill the gap otherwise a connection may be established between the source region 22 and the drain region 23, which may lead to a short circuit.

The source region 22 and the drain region 23 may extend into the substrate under the spacer 25. Likewise, the body contact region 24 may also extend into the substrate under the spacer 25. Projections of the main gate 211, the extended gate 212 and the insulating dielectric layer 26 on a plane normal to the surface of the substrate may be contiguous with those of the source region 22 and the drain region 23, or not. A projection of the extended gate 212 on a plane normal to the surface of the substrate may be contiguous with that of the body contact region 24, or not.

The semiconductor device further includes conductive plugs 27 formed on the main gate 211, the source region 22, the drain region 23 and the body contact region 24, but not on the extended gate 212. With this arrangement, through the conductive plugs 27, a voltage can be applied to the main gate 211, the source region 22, the drain region 23 and the body contact region 24, but not to the extended gate 212.

In case of the T-shaped structure being made of the main gate 211, the extended gate 212 and the insulating dielectric layer 26 that connects the two, the conductive plugs 27 are preferably formed on the main gate 211 on the trench isolation structure. This can ensure reliability and performance stability of the semiconductor device.

Ion implantation for forming the source region 22, the drain region 23 and the body contact region 24 should take into account the critical dimensions (CDs) of processes used to form the extended gate 212, the body contact region 24, the source region 22 and the drain region 23 and variations in alignment accuracy of photomasks used herein, in order to avoid the resulting source region 22, drain region 23 and body contact region 24 from having undesirable extents. Accordingly, ion implantation for forming the source region 22, the drain region 23 and the body contact region 24 is desired to be performed within areas each extending from over the substrate to over the extended gate 212 (e.g., to the border BB′ of the ion-implanted regions B1 and B2 in FIGS. 2 to 3). Moreover, a length of the extended gate 212 measured in the direction pointing from the source region 22 to the body contact region 24 (e.g., the gate length L2 of the extended gate 212 measured in the direction pointing from the source region 22 to the body contact region 24 in FIGS. 2 to 3) should be adequately long (e.g., not less than 0.3 μm). On the other hand, if the extended gate 212 is too long, there will be significant parasitic capacitance between the extended gate 212, the gate dielectric layer and the substrate, which will degrade the performance of the semiconductor device.

To address this, in the semiconductor device of the present disclosure, the main gate 211 and the extended gate 212 in the gate layer 21 are separated apart and connected by the insulating dielectric layer 26. With this arrangement, the main gate 211 and the extended gate 212 are insulated from each other, allowing a voltage to be applied to the main gate 211, but not to the extended gate 212. This can completely eliminate parasitic capacitance between the extended gate 212, the gate dielectric layer and the substrate while ensuring that the extents of the source region 22, the drain region 23 and the body contact region 24 are as desired and allow the semiconductor device to perform as intended. Thus, the gate layer 21 can function as desired, and performance of the semiconductor device will not be degraded due to the presence of parasitic capacitance. This improves the performance of the semiconductor device, in particular when it is sensitive to gate capacitance (e.g., a low noise amplifier).

In summary, the present disclosure provides a semiconductor device including: a substrate; a gate layer over the substrate, which includes a main and an extended gate spaced apart from each other; and an insulating dielectric layer formed on the substrate and connecting the a main and an extended gate. The gate layer in this semiconductor device can function as desired while allowing the performance of the semiconductor device from being degraded due to the presence of parasitic capacitance.

In one embodiment of the present disclosure, there is provided a method of fabricating a semiconductor device. FIG. 4 shows a flowchart of this method. As shown, the method includes the steps of:
S1) providing a substrate;
S2) forming a gate layer over the substrate, which includes a main gate and an extended gate separated apart from each other; and
S3) forming an insulating dielectric layer on the substrate, which connects the main and the extended gate.

The method of this embodiment is described in detail below with reference to FIGS. 2 to 3.

In step S1, the substrate is provided.

The substrate may be either a single-layer structure, or a multi-layer structure consisting of multiple layers of the same or different materials. Without limitation, examples of the material of the substrate may include semiconductor materials, such as Si, SiGe, SiGeC, SiC, GaAs, InAs, InP and other III/V or II/VI compound semiconductors, or the substrate may be a layered substrate, such as Si/SiGe, Si/SiC, silicon on insulator (SOI) or silicon germanium on insulator (SiGeOI).

An active area (not shown) is formed in the substrate, which is surrounded by a trench isolation structure (not shown). A top surface of the trench isolation structure may be flush with, slightly lower than, or slightly higher than a top surface of the substrate. The trench isolation structure may be made of silicon oxide, silicon oxynitride or the like.

In step S2, the gate layer 21 is formed over the substrate. The gate layer 21 includes the main gate 211 and the extended gates 212 that are separated apart from each other. That is, there is a gap between the main gate 211 and the extended gate 212, which electrically isolates them from each other.

A gate material may be deposited over the substrate and the trench isolation structure, and an etching process may be then carried out to form, in the gate material, a pattern corresponding to the gate layer 21. That is, the gate material is etched to allow the main gate 211 and the extended gate 212 to be spaced apart from each other.

Before the gate layer 21 is formed over the substrate, a gate dielectric layer (not shown) may be formed on the substrate. The gate layer 21 may be formed on the gate dielectric layer, the gate dielectric layer is sandwiched between the gate layer 21 and the substrate. The gate layer 21, the gate dielectric layer and the substrate make up a capacitive structure.

The gate dielectric layer may be made of silicon oxide (with a relative dielectric constant of 4.1) or another dielectric material. The gate dielectric layer may be made of a low-k material. Constructing the gate dielectric layer with a low-k material can reduce the capacitance.

In step S3, the insulating dielectric layer 26 that connects the main gate 211 and the extended gate 212 is formed over the substrate. That is, the insulating dielectric layer 26 fills the gap between, and thereby connects, the main gate 211 and the extended gate 212. These connections are mechanical, but not electrical. That is, the insulating dielectric layer 26 electrically insulates the main gate 211 and the extended gate 212 from each other.

The insulating dielectric layer 26 includes at least one of silicon oxide, silicon nitride, silicon oxynitride and optionally other materials.

As shown in FIG. 2, the main gate 211 and the extended gate 212 may make up a T-shaped structure, together with the insulating dielectric layer 26 that connects them. In this case, the main gate 211 provides a vertical arm of the T-shaped structure, and the extended gate 212 provides a horizontal arm of the T-shaped structure. The insulating dielectric layer 26 may be located at the end of the vertical arm of the T-shaped structure closer to the horizontal arm, or on the side of the horizontal arm of the T-shaped structure adjacent to the vertical arm. Alternatively, as shown in FIG. 3, the main gate 211 and the extended gate 212 may make up an H-shaped structure, together with the insulating dielectric layer 26 that connects them. In this case, the main gate 211 provides a horizontal arm of the H-shaped structure, and the extended gate 212 provides vertical arms of the H-shaped structure. The insulating dielectric layer 26 may be located at the opposite ends of the horizontal arm of the H-shaped structure, or on the sides of the vertical arms of the H-shaped structure adjacent to the horizontal arm.

In one embodiment, the extended gate 212 extends at opposite ends from over the active area to over the trench isolation structure. In case of the T-shaped structure being made of the main gate 211, the extended gate 212 and the insulating dielectric layer 26 that connects the two, according to one embodiment, the main gate 211 may extend, at the end away from the extended gate 212, from over the active area to over the trench isolation structure.

After the gate layer 21 is formed over the substrate, the method further includes: forming a spacer 25 on sidewalls of the main gate 211 and the extended gate 212.

Preferably, the insulating dielectric layer 26 and the spacer 25 are formed of the same material in a single process. That is, at the same time as the spacer 25 is formed on the sidewalls of the main gate 211 and the extended gate 212, the material of the spacer 25 is also filled in the gap between the main gate 211 and the extended gate 212. The material of the spacer 25 filled in the gap acts as the insulating dielectric layer 26. That is, the main gate 211 and the extended gate 212 are connected by part of the spacer 25 (that acts as the insulating dielectric layer 26).

In one embodiment, a layer of insulating material is formed on the substrate and the gate layer 21, which covers a top surface of the substrate and the sidewalls and a top surface of the gate layer 21 and fills the gap between the main gate 211 and the extended gate 212, and portions of the layer of insulating material on the top surfaces of the substrate and the gate layer 21 are then removed by maskless etching (performed normal to the substrate). The remainder of the layer of insulating material provides both the spacer 25 on the sidewalls of the gate layer 21 and the insulating dielectric layer 26 in the gap between the main gate 211 and the extended gate 212.

In an alternative embodiment, the insulating dielectric layer 26 and the spacer 25 may be formed in separate processes. In this case, the spacer 25 may also cover sidewalls of the insulating dielectric layer 26.

In an alternative embodiment, the insulating dielectric layer 26 may be formed only in the gap between the main gate 211 and the extended gate 212.

The insulating dielectric layer 26 should completely fill the gap otherwise a connection may be established between the source region 22 and the drain region 23, which may lead to a short circuit.

After the insulating dielectric layer 26 and the spacer 25 are formed, the method further includes: forming, in the substrate, a source region 22 and a drain region 23 on opposite sides of the main gate 211 and the insulating dielectric layer 26 and a body contact region 24 on the side of the extended gate 212 away from the main gate 211.

The formation of the source region 22 and the drain region 23 in the substrate on the opposite sides of the main gate 211 and the insulating dielectric layer 26 may precede, or succeed, the formation of the body contact region 24 in the substrate on the side of the extended gate 212 away from the main gate 211.

The insulating dielectric layer 26 can prevent a connection from being established between the source region 22 and the drain region 23 during the formation of the two regions by ion implantation, which can lead to a short circuit.

A region under the main gate 211 between the source region 22 and the drain region 23 functions as a channel region. The body contact region 24 is formed to connect the substrate under the channel region (i.e., a body region). The trench isolation structure surrounds the source region 22, the drain region 23 and the body contact region 24.

The main gate 211 acts as a gate electrode of the semiconductor device being fabricated, and the extended gate 212 acts to isolate both the source region 22 and the drain region 23 from the body contact region 24.

The source region 22 and the drain region 23 are of the same doping type, which is opposite to that of the body contact region 24. When the doping types of the body contact region 24 and the source region 22 are opposite, the semiconductor device is an enhancement-mode field effect transistor.

In case of the body contact region 24 and the source region 22 being of opposite doping types, if the source region 22 and the drain region 23 are n-type regions, then the body contact region 24 is a p-type region. On the contrary, if the source region 22 and the drain region 23 are p-type regions, then the body contact region 24 is an n-type region.

The source region 22 and the drain region 23 may extend into the substrate under the spacer 25. Likewise, the body contact region 24 may also extend into the substrate under the spacer 25. Projections of the main gate 211, the extended gate 212 and the insulating dielectric layer 26 on a plane normal to the surface of the substrate may be contiguous with those of the source region 22 and the drain region 23, or not. A projection of the extended gate 212 on a plane normal to the surface of the substrate may be contiguous with that of the body contact region 24, or not.

The method further includes: forming conductive plugs 27 on the main gate 211, the source region 22, the drain region 23 and the body contact region 24, but not on the extended gate 212. In this way, through the conductive plugs 27, a voltage can be applied to the main gate 211, the source region 22, the drain region 23 and the body contact region 24, but not to the extended gate 212.

In case of the T-shaped structure being made of the main gate 211, the extended gate 212 and the insulating dielectric layer 26 that connects the two, the conductive plugs 27 are preferably formed on the main gate 211 on the trench isolation structure. This can ensure reliability and performance stability of the semiconductor device being fabricated.

Ion implantation for forming the source region 22, the drain region 23 and the body contact region 24 should take into account the critical dimensions (CDs) of processes used to form the extended gate 212, the body contact region 24, the source region 22 and the drain region 23 and variations in alignment accuracy of photomasks used herein, in order to avoid the resulting source region 22, drain region 23 and body contact region 24 from having undesirable extents. Accordingly, ion implantation for forming the source region 22, the drain region 23 and the body contact region 24 is desired to be performed within areas each extending from over the substrate to over the extended gate 212 (e.g., to the border BB′ of the ion-implanted regions B1 and B2 in FIGS. 2 to 3). Moreover, a length of the extended gate 212 measured in the direction pointing from the source region 22 to the body contact region 24 (e.g., the gate length L2 of the extended gate 212 measured in the direction pointing from the source region 22 to the body contact region 24 in FIGS. 2 to 3) should be adequately long (e.g., not less than 0.3 μm). On the other hand, if the extended gate 212 is too long, there will be significant parasitic capacitance between the extended gate 212, the gate dielectric layer and the substrate, which will degrade the performance of the semiconductor device.

To address this, in the method of the present disclosure, the main gate 211 and the extended gate 212 in the gate layer 21 are separated apart and connected by the insulating dielectric layer 26. With this arrangement, the main gate 211 and the extended gate 212 are insulated from each other, allowing a voltage to be applied to the main gate 211, but not to the extended gate 212. This can completely eliminate parasitic capacitance between the extended gate 212, the gate dielectric layer and the substrate while ensuring that the extents of the source region 22, the drain region 23 and the body contact region 24 are as desired and allow the semiconductor device to perform as intended. Thus, the gate layer 21 can function as desired, and performance of the semiconductor device will not be degraded due to the presence of parasitic capacitance. This improves the performance of the semiconductor device, in particular when it is sensitive to gate capacitance (e.g., a low noise amplifier).

In summary, the present disclosure provides a method of fabricating a semiconductor device, which includes: providing a substrate; forming a gate layer over the substrate, which includes a main and an extended gate separated apart from each other; and forming an insulating dielectric layer on the substrate, which connects the a main and an extended gate. The method allows the gate layer to function as desired while avoiding performance of the resulting semiconductor device from being degraded due to the presence of parasitic capacitance.

The description presented above is merely that of a few preferred embodiments of the present disclosure and is not intended to limit the scope thereof in any sense. Any and all changes and modifications made by those of ordinary skill in the art based on the above teachings fall within the scope of the disclosure.

1. A semiconductor device, comprising:
a substrate;
a gate layer formed over the substrate, the gate layer comprising a main gate and an extended gate spaced apart from each other; and
an insulating dielectric layer formed on the substrate, and the insulating dielectric layer connecting the main gate and the extended gate.

2. The semiconductor device of claim 1, wherein the main gate and the extended gate make up a T-shaped structure, together with the insulating dielectric layer that connects the main gate and the extended gate, the main gate provides a vertical arm of the T-shaped structure and the extended gate provides a horizontal arm of the T-shaped structure; or
wherein the main gate and the extended gate make up an H-shaped structure, together with the insulating dielectric layer that connects the main gate and the extended gate, the main gate provides a horizontal arm of the H-shaped structure and the extended gate provides vertical arms of the H-shaped structure.

3. The semiconductor device of claim 1, wherein an active area is formed in the substrate, which is surrounded by a trench isolation structure.

4. The semiconductor device of claim 1, further comprising:
a spacer formed on sidewalls of the main gate and the extended gate.

5. The semiconductor device of claim 4, wherein the insulating dielectric layer and the spacer are formed of the same material in a single process.

6. The semiconductor device of claim 1, further comprising:
a source region and a drain region formed both in the substrate on opposite sides of the main gate and the insulating dielectric layer; and
a body contact region formed in the substrate on a side of the extended gate away from the main gate.

7. The semiconductor device of claim 6, further comprising:
conductive plugs formed on the main gate, the source region, the drain region and the body contact region.

8. The semiconductor device of claim 1, wherein the insulating dielectric layer comprises at least one of silicon oxide, silicon nitride and silicon oxynitride.

9. The semiconductor device of claim 1, further comprising a gate dielectric layer formed between the gate layer and the substrate.

10. The semiconductor device of claim 9, wherein the gate dielectric layer is formed of a low-k material.

11. A method of fabricating a semiconductor device, comprising:
providing a substrate;
forming a gate layer over the substrate, the gate layer comprising a main gate and an extended gate spaced apart from each other; and
forming an insulating dielectric layer on the substrate, and the insulating dielectric layer connecting the main gate and the extended gate.

12. The method of claim 11, wherein the main gate and the extended gate make up a T-shaped structure, together with the insulating dielectric layer that connects the main gate and the extended gate, the main gate provides a vertical arm of the T-shaped structure and the extended gate provides a horizontal arm of the T-shaped structure, or wherein the main gate and the extended gate make up an H-shaped structure, together with the insulating dielectric layer that connects the main gate and the extended gate, the main gate provides a horizontal arm of the H-shaped structure and the extended gate provides vertical arms of the H-shaped structure.

13. The method of claim 11, further comprising, after the gate layer is formed over the substrate,
forming a spacer formed on sidewalls of the main gate and the extended gate.

14. The method of claim 13, wherein the insulating dielectric layer and the spacer are formed of the same material in a single process.

15. The method of claim 11, further comprising:
forming a source region and a drain region formed both in the substrate on opposite sides of the main gate and the insulating dielectric layer; and forming a body contact region formed in the substrate on a side of the extended gate away from the main gate.

16. The method of claim 15, further comprising:
forming conductive plugs formed on the main gate, the source region, the drain region and the body contact region.

17. The method of claim 11, wherein the insulating dielectric layer comprises at least one of silicon oxide, silicon nitride and silicon oxynitride.

18. The method of claim 13, forming the spacer and the insulating dielectric layer comprising:
forming a layer of insulating material on the substrate and the gate layer, which covers a top surface of the substrate and the sidewalls and a top surface of the gate layer and fills a gap between the main gate and the extended gate, and a portion of the layer of insulating material on the top surface of the substrate and the top surface of the gate layer are then removed by maskless etching, the remainder of the layer of insulating material provides both the spacer on the sidewalls of the gate layer and the insulating dielectric layer in the gap between the main gate and the extended gate.

19. The method of claim 18, wherein the insulating dielectric layer is formed only in the gap between the main gate and the extended gate.

20. The method of claim 11, further comprising forming a gate dielectric layer between the gate layer and the substrate, wherein the gate dielectric layer is formed of a low-k material.
